(19) United States
(12) Patent Application Publication
(10) Pub. No.: US 2006/0205134 A1
(43) Pub. Date: Sep. 14, 2006

(54) METHOD FOR MANUFACTURING A SEMICONDUCTOR DEVICE AND METHOD FOR REGULATING SPEED OF FORMING AN INSULATING FILM

(75) Inventor: Hidetomo NISHIMURA, Tokyo (JP)

Correspondence Address: STEVEN ROBERTS;SHINJYU GLOBAL IP, SOUTH FOREST BLDG., 11TH FLOOR, 1-4-19, MINAMIMORI-MACHI, KITA-KU, OSAKA, 530-0054, JP

(73) Assignee: OKI ELECTRIC INDUSTRY CO., LTD., Tokyo (JP)

(21) Appl. No.: 11/276,404

(22) Filed: Feb. 28, 2006

(30) Foreign Application Priority Data
Mar. 10, 2005 (JP) 2005/067620

(51) Int. Cl. H01L 21/8238; H01L 21/336

(52) U.S. Cl. 438/199; 438/301

(57) ABSTRACT

A method for manufacturing a semiconductor device including sidewall insulating films with different thicknesses includes the steps of (a) selectively forming first and second gate electrode structures on first and second active regions of a silicon substrate respectively, (b) forming a first silicon oxide film on the first and second active regions, (c) forming first and second lightly-doped regions in the first and second active regions respectively, (d) removing the first silicon oxide film formed on the first active region while leaving the first silicon oxide film formed on the second active region, (e) forming an insulating film on the first region and an insulating film on the first silicon oxide film formed on the second active region, and (f) forming a first sidewall insulating film on a first gate electrode structure's sidewall while forming a second sidewall insulating film on a second gate electrode structure's sidewall.

### BACKGROUND OF THE INVENTION

### Field of the Invention

The present invention relates to a method for manufacturing a semiconductor device, especially a method for forming sidewall insulating films with different thicknesses on the same semiconductor substrate and a method for manufacturing a semiconductor device comprising a plurality of transistors having sidewall insulating films with different thicknesses.

In recent years, semiconductor devices in which an n-channel metal oxide semiconductor (MOS) transistor and a p-channel metal oxide semiconductor (MOS) transistor are formed on the same semiconductor substrate have been widely used. However, the diffusion coefficient of boron ion (B⁺) used for forming a p-type diffusion layer is generally larger than that of arsenic ion (As⁺) used for forming a n-type diffusion layer. Therefore, if a sidewall insulating film of a gate electrode of a n-channel MOS transistor and that of a gate electrode of a p-channel MOS transistor are formed of the same thickness, B⁺ in the p-type diffusion layer diffuses into a channel region formed directly below a gate electrode. This is because the diffusion layer is formed in a self-alignment process. Thus distance between channel regions is decreased, and this causes the short channel effect and further causes a problem in which the required transistor properties cannot be obtained.

In the present invention, thickness of a sidewall insulating film means thickness of an insulating film comprising a sidewall, and this corresponds to the length of the sidewall in the horizontal direction (i.e., width of the sidewall). The length of a lightly doped drain (LDD) region in the horizontal direction (i.e., width of the LDD region) is defined by the width of the sidewall. Also, “the horizontal direction” means the direction parallel to an interface between a semiconductor substrate and an insulating film.

To solve the above described problem, a technique to form a sidewall insulating film of a p-channel MOS transistor more thickly than a n-channel MOS transistor has been heretofore provided. In this technique, a n-type heavily-doped source/drain region and a p-type heavily-doped source/drain region are then formed in a self-alignment manner in an ion implantation process in which a gate electrode and a sidewall insulating film are used as masks. As a result, a wide lightly-doped region is formed directly below the thick sidewall insulating film of the p-channel MOS transistor, and the distance between the p-type heavily-doped source/drain region and the gate electrode can be formed longer than the distance between the n-type heavily-doped source/drain region and the gate electrode. Therefore, B⁺ in the p-type diffusion layer can be prevented from diffusing into the channel region formed directly below the gate electrode.

Japanese Patent Application Publication JP-A-2000-349167 (especially paragraph numbers 0021-0023, and 0037, and FIGS. 6 and 13) discloses technology to form sidewall insulating films of different thicknesses without increasing the number of the manufacturing steps. Here, when an ozone tetraethoxysilane non-doped silicate glass (hereinafter called O₃-TEOS-NSG) film is deposited on a n-type lightly-doped region (i.e., a n-type LDD region) and a p-type lightly-doped region (i.e., a p-type LDD region) with the chemical vapor deposition (CVD) method, the speed of depositing an O₃-TEOS-NSG film on the n-type LDD region and that of depositing an O₃-TEOS-NSG film on the p-type LDD region are different because different types of impurities are doped in those regions, respectively. In this conventional technology, the thin O₃-TEOS-NSG film is formed on the n-type LDD region and the thick O₃-TEOS-NSG film is formed on the p-type LDD region because the speed of depositing the 0₃-TEOS-NSG film depends on the type of the substrate on which the film is deposited. After those O₃-TEOS-NSG films are formed, anisotropic etching is conducted for the O₃-TEOS-NSG films, and thus a thin sidewall insulating film of the n-channel MOS transistor and a thick sidewall insulating film of the p-channel MOS transistor are formed.

As described above, with the conventional method, the speed of depositing an O₃-TEOS-NSG film depends on the type and the concentration of impurities doped into a substrate (i.e., a lightly-doped region). The ratio between the thicknesses of the sidewall insulating films depends on the ratio between the thicknesses of the O₃-TEOS-NSG films. Also, the ratio between the thicknesses of the O₃-TEOS-NSG films depends on the ratio between the speeds of depositing the O₃-TEOS-NSG films. Furthermore, the ratio between the speeds of depositing the O₃-TEOS-NSG films depends on the difference between the types and concentrations of impurities doped into the substrate (i.e., a lightly-doped region). Therefore, in the above described conventional method, it has been required to regulate the concentration of the impurities doped into a lightly-doped region (i.e., a LDD region) or to properly select the type of impurities doped in a lightly-doped region for the purpose of forming a sidewall insulating film of the desired thickness. However, the regulation of the concentration of impurities doped into a lightly-doped region or the selection of the type of impurities doped into a lightly-doped region to form a sidewall insulating film with the desired thickness has to be done within an allowance of the device design. Therefore, the scope of the above described conventional method has been actually limited

Furthermore, semiconductor devices in which a high voltage metal oxide semiconductor field effect transistor (a high voltage MOSFET) and a high speed metal oxide semiconductor field transistor (a high speed MOSFET) are formed on the same semiconductor substrate has also been widely used. In this type of the semiconductor device, a thick sidewall insulating film is required for the high voltage MOSFET, and a thin sidewall insulating film is required for the high speed MOSFET. If the conductivity types (i.e., p-type or n-type) of the channels of the MOSFETs with different properties are the same, it is impossible to make a difference between the speeds of depositing the O₃-TEOS-NSG films with use of the difference in the types of impurities doped into a substrate (i.e., a lightly-doped region). Therefore, it has been difficult to apply the above described conventional method to a semiconductor device in which different types of MOSFETs with different properties are formed on the same semiconductor substrate while the conductivity types of channels of MOSFETs are the same.

In view of the above, it will be apparent to those skilled in the art from this disclosure that there exists a need for an improved method for manufacturing a semiconductor device. This invention addresses this need in the art as well as other needs, which will become apparent to those skilled in the art from this disclosure.

### SUMMARY OF THE INVENTION

It is therefore an object of the present invention to provide a method for forming O₃-TEOS-NSG films with different thicknesses on different regions without depending on the types or concentrations of impurities doped into a lightly-doped region formed on a silicon substrate.

Furthermore, it is also an object of the present invention to provide a method for manufacturing a semiconductor device comprising O₃-TEOS-NSG sidewall insulating films with different thicknesses on different regions without depending on the types or concentrations of impurities doped into a lightly-doped region formed on a silicon substrate.

The method for manufacturing a semiconductor device including sidewall insulating films with different thicknesses is comprised of the steps of: (a) selectively forming a first gate electrode structure and a second gate electrode structure on a first active region and a second active region of a silicon substrate, respectively, (b) forming a first silicon oxide film on said first active region and said second active region, (c) forming a first lightly-doped region and a second lightly-doped region in said first active region and said second active region, respectively, by ion-implanting impurities into said first active region and said second active region through said first silicon oxide film, (d) removing said first silicon oxide film formed on said first active region while leaving said first silicon oxide film formed on said second active region, (e) forming an insulating film on said first region of said silicon substrate and an insulating film on said first silicon oxide film formed on said second active region of said silicon substrate with a thermal decomposition CVD method in which ozone and tetraethoxysilane are used as materials, said insulating film formed on said first region of said silicon substrate being formed more thickly than said insulating film formed on said first silicon oxide film formed on said second active region of said silicon substrate, and (f) forming a first sidewall insulating film on a sidewall of said first gate electrode structure while forming a second sidewall insulating film on a sidewall of said second gate electrode structure, said first sidewall being formed more thickly than said second sidewall. Here, the gate electrode structure means a structure comprising a gate electrode and an insulating film.

According to the present invention, an O₃-TEOS-NSG film is formed both on a first region comprised of silicon and on a second region comprised of silicon oxide with a thermal decomposition CVD method in which O₃ and TEOS are used as materials. In this case, it is possible to regulate the ratio of the speed of forming the insulating film to be formed on the second region comprised of silicon oxide with respect to the speed of forming the insulating film to be formed on the first region comprised of silicon, by regulating only the flow rate of O₃ with respect to TEOS. Selecting silicon and silicon oxide as the substrate regions makes it possible to widely regulate difference between the thickness of the O₃-TEOS-NSG film formed on the first active region and that of the O₃-TEOS-NSG film formed on the second active region by regulating only the flow rate of O₃ with respect to TEOS in the thermal decomposition CVD method, without depending on the types and concentrations of impurities doped into a first lightly-doped region in the first active region and impurities doped into a second lightly-doped region in the second active region.

### BRIEF DESCRIPTION OF THE DRAWINGS

Referring now to the attached drawings which form a part of this original disclosure:

FIGS. 1A to 1C are partial vertical cross-section diagrams showing a method for manufacturing a semiconductor device in accordance with a first embodiment of the present invention.

FIGS. 2A to 2C are partial vertical cross-section diagrams showing a method for manufacturing a semiconductor device in accordance with the first embodiment of the present invention.

FIGS. 3A to 3C are partial vertical cross-section diagrams showing a method for manufacturing a semiconductor device in accordance with the first embodiment of the present invention.

FIGS. 4A to 4C are partial vertical cross-section diagrams showing a method for manufacturing a semiconductor device in accordance with the first embodiment of the present invention.

FIG. 5 is partial vertical cross-section diagrams showing a method for manufacturing a semiconductor device in accordance with the first embodiment of the present invention.

FIG. 6 is a chart showing the relationship between the flow rate of O₃ with respect to TEOS and the speed ratio of forming an O₃-TEOS-NSG film on silicon with respect to forming an O₃-TEOS-NSG film on silicon dioxide in the thermal decomposition CVD.

FIGS. 7A to 7C are partial vertical cross-section diagrams showing a method for manufacturing a semiconductor device in accordance with a second embodiment of the present invention.

FIGS. 8A to 8C are partial vertical cross-section diagrams showing a method for manufacturing a semiconductor device in accordance with the second embodiment of the present invention.

FIGS. 9A to 9C are partial vertical cross-section diagrams showing a method for manufacturing a semiconductor device in accordance with the second embodiment of the present invention.

FIGS. 10A to 10C are partial vertical cross-section diagrams showing a method for manufacturing a semiconductor device in accordance with the second embodiment of the present invention.

FIG. 11 is partial vertical cross-section diagrams showing a method for manufacturing a semiconductor device in accordance with the second embodiment of the present invention.

FIG. 12 is a chart showing the relationship between the flow rate of O₃ with respect to TEOS and the speed ratio of forming an O₃-TEOS-NSG film on silicon in which H⁺ is implanted with respect to forming an O₃-TEOS-NSG film on silicon in which H⁺ is not implanted in the thermal decomposition CVD.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

Referring now to the drawings, preferred embodiments of the present invention will be described in detail.

### FIRST EMBODIMENT

Method for Manufacturing a Semiconductor Device

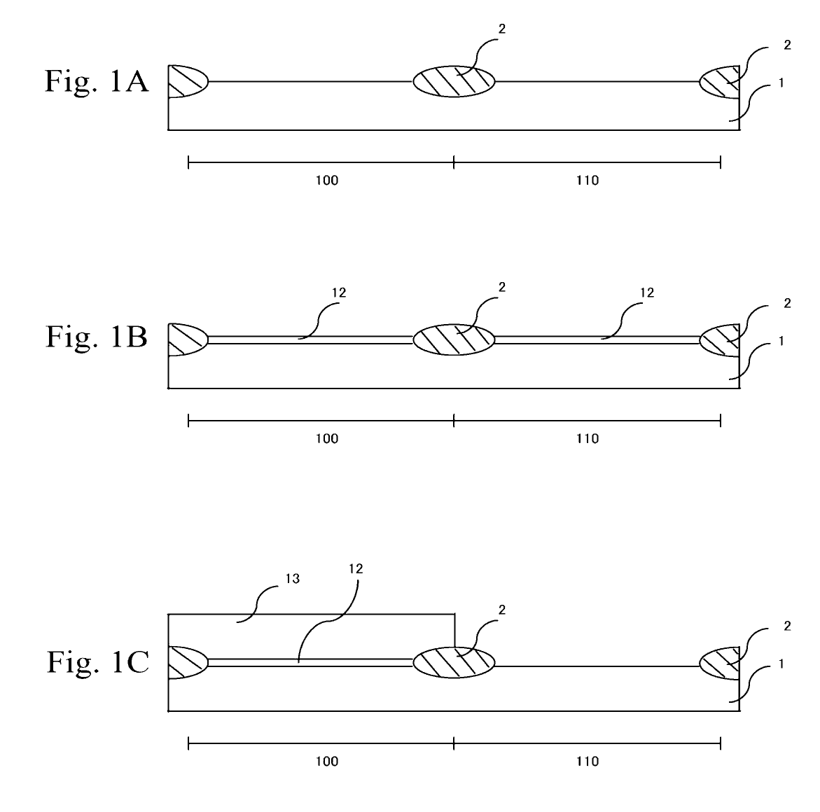

FIGS. 1A to 1C, 2A to 2C, 3A to 3C, 4A to 4C, and 5 are partial vertical cross-section diagrams showing a method for manufacturing a semiconductor device in accordance with the first embodiment of the present invention. According to the first embodiment, a high voltage MOSFET and a high speed MOSFET are formed on the same semiconductor substrate. A thick sidewall insulating film is required for the high voltage MOSFET, because the gate voltage of the high voltage MOSFET is high. On the other hand, a thin sidewall insulating film is required for the high speed MOSFET, because the gate voltage of the high speed MOSFET is low.

As shown in FIG. 1A, a field oxide film 2 is formed in element separation regions of a p-type silicon substrate 1 with the local oxidation of silicon (LOCOS) method. Thus a first active region 100 and a second active region 110 are defined by the field oxide film 2. Here, the first active region 100 is a region on which the high voltage MOSFET is formed and the second active region 110 is a region on which a high speed MOSFET is formed.

As shown in FIG. 1B, a silicon dioxide film 12 of 365 Å in thickness is formed on the first active region 100 and on the second active region 110 of the p-type silicon substrate 1.

As shown in FIG. 1C, a resist pattern 13 is formed on the silicon dioxide film 12 formed on the first active region 100 with a heretofore known lithography technique. After this, the silicon dioxide film 12 is etched using the resist pattern 13 as an etching mask. Thus, the silicon dioxide film 12 formed on the second active region 110 is selectively eliminated while the silicon dioxide film 12 formed on the first active region 100 is left.

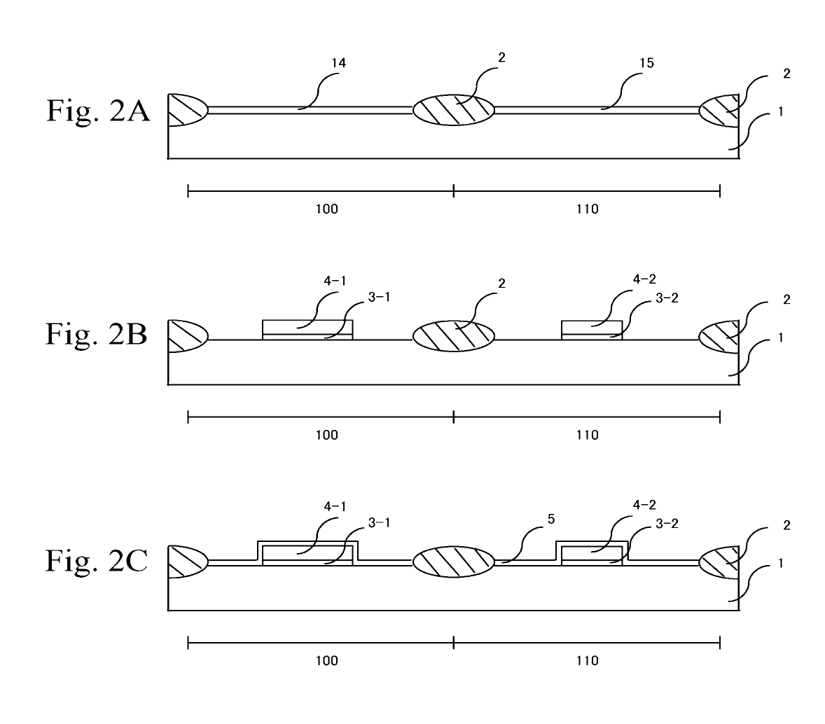

As shown in FIG. 2A, the resist pattern 13 is eliminated, and then a silicon dioxide film is formed on the silicon dioxide film 12 formed on the first active region 100 and on the second active region 110 of the p-type silicon substrate 1 with a heretofore known method. As a result, a silicon dioxide film 14 of 400 Å in thickness is formed on the first active region 100 of the silicon substrate 1, and a silicon dioxide film 15 of 75 Å in thickness is formed on the second active region 110 of the silicon substrate 1.

As shown in FIG. 2B, a polysilicon film is formed on the silicon dioxide films 14 and 15, and the field oxide film 2, and impurities are ion-implanted into this polysilicon film. Then, the polysilicon film including the impurities and the silicon dioxide films 14 and 15 are patterned with a heretofore known lithography technique and etching technique. Thus, a first gate oxide film 3-1 and a first gate electrode 4-1 are formed on the first active region 100, and a second gate oxide film 3-2 and a second gate electrode 4-2 are formed on the second active region 110.

As shown in FIG. 2C, a silicon dioxide film 5 of 100-500 Å in thickness is formed with the thermal oxidation method or the CVD method, so that it covers the upper surface of the first active region 100, the lateral surface of the first gate oxide film 3-1, the upper and the lateral surfaces of the first gate electrode 4-1, as well as the upper surface of the second active region 110, the lateral surface of the second gate oxide film 3-2, the upper and the lateral surfaces of the second gate electrode 4-2.

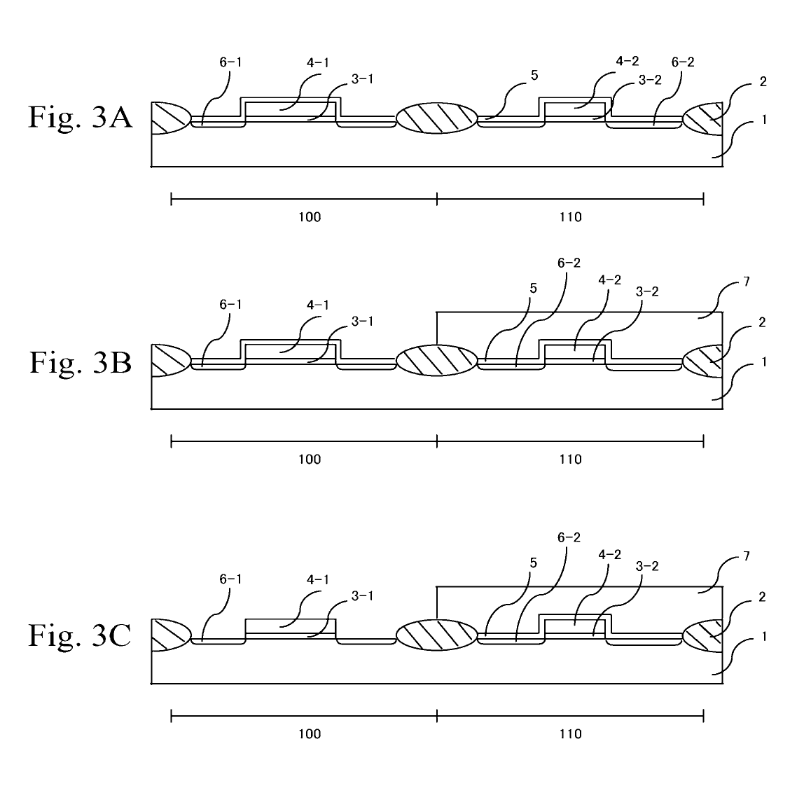

As shown in FIG. 3A, the n-type impurity arsenic (As) is implanted into the silicon substrate 1 using the first gate electrode 4-1, the second gate electrode 4-2, and the field oxide film 2 as masks with an acceleration energy of 20 keV and the dose amount of 1.2×10¹⁴ cm⁻². As a result, a first lightly-doped region 6-1, which is self-aligned with respect to the first gate electrode 4-1, is formed in the first active region 100 of the silicon substrate 1. On the other hand, a second lightly-doped region 6-2, which is self-aligned with respect to the second gate electrode 4-2, is formed in the second active region 110 of the silicon substrate 1.

Here, the thickness of the sufficiently thin silicon dioxide film 5 enables the accelerated ions to pass through the silicon dioxide film 5 and to be implanted into the silicon substrate 1. Also, the silicon dioxide film 5 formed on the surface of the silicon substrate 1 prevents the surface of the silicon substrate 1 from being damaged by the ion implantation. Furthermore, the silicon dioxide film 5 prevents the surface of the silicon substrate 1 from being contaminated by metal.

Here, the first lightly-doped region 6-1 and the second lightly-doped region 6-2 are simultaneously formed by conducting the ion implantation once under the same conditions. However, the method of forming these regions is not limited to the above described method. For example, the first lightly-doped region 6-1 and the second lightly-doped region 6-2 may be separately formed in discrete ion implantation processes under different conditions.

As shown in FIG. 3B, a resist pattern 7 is formed on the silicon dioxide film 5 formed on the second active region 110 side with a heretofore known lithography technique.

As shown in FIG. 3C, the silicon dioxide film 5 is etched using the resist pattern 7 as an etching mask. Thus, the silicon dioxide film 5 formed on the first active region 100 side is selectively eliminated, and the silicon dioxide film 5 formed on the second active region 110 side is left. As a result, on the first active region 100 side, the upper surface of the first lightly-doped region 6-1, the upper and lateral surfaces of the first gate electrode 4-1, and the lateral surface of the first gate oxide film 3-1 are exposed.

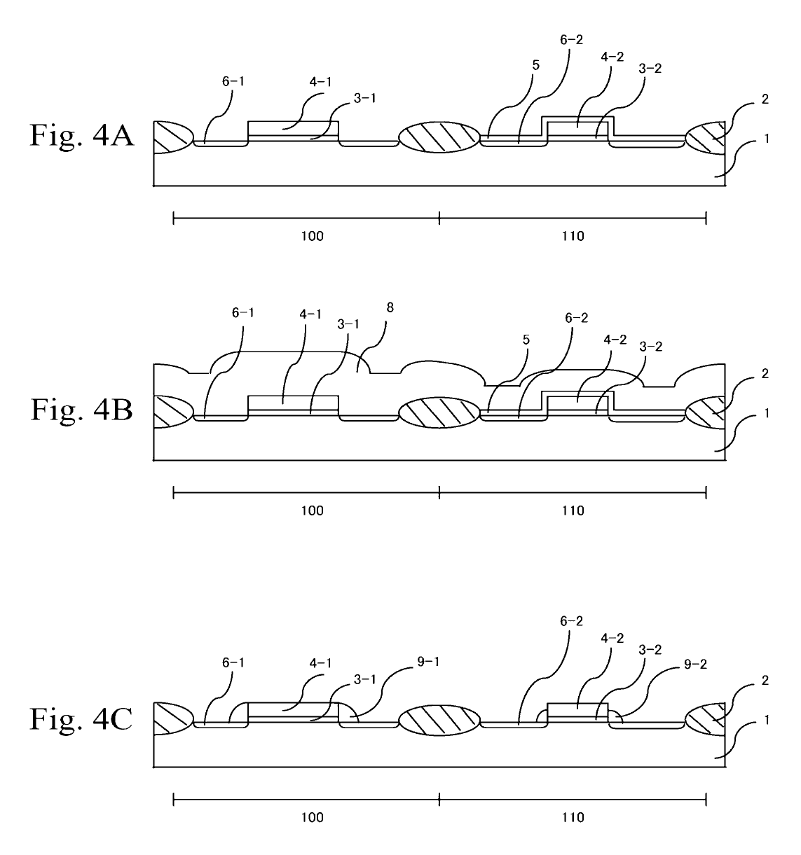

As shown in FIG. 4A, the resist pattern 7 is eliminated and thus the upper surface of the silicon dioxide film 5 formed on the second active region 110 side is exposed. In other words, the second lightly-doped region 6-2 and the second gate electrode 4-2 formed on the second active region 110 side are covered with the silicon dioxide film 5, while the first lightly-doped region 6-1 and the first gate electrode 4-1 formed on the first active region 100 side are exposed.

As shown in FIG. 4B, an O₃-TEOS-NSG film 8 is deposited so that it covers the field oxide film 2, the silicon dioxide film 5 formed on the second active region 110 side, the lightly-doped region 6-1 formed on the first active region 100, the upper and lateral sides of the first electrode 4-1 formed on the first active region 100, and the lateral sides of the first gate oxide film 3-1 with the thermal decomposition CVD method in which O₃ and TEOS are used as materials.

In forming the O₃-TEOS-NSG film 8, the thermal decomposition CVD method can be conducted under the desired conditions. However, as a typical example, the following conditions are set. That is, the flow rate of O₃ with respect to TEOS is set to be 7.5 and the pressure is set to be a normal pressure, and the temperature is set to be 400 degrees Celsius. The thickness of the O₃-TEOS-NSG film 8 formed on the first active region 100 side is 5960 Å and that of the O₃-TEOS-NSG film 8 formed on the second active region 110 side is 4239 Å. In other words, when the flow rate of O₃ with respect to TEOS is set to be 7.5, the thickness of the O₃-TEOS-NSG film 8 formed on the second active region 110 side is 71.12% of that of the O₃-TEOS-NSG film 8 formed on the first active region 100 side. In depositing the O₃-TEOS-NSG film 8, the pressure may be typically set to be 400-760 Torr and the temperature may be typically set to be 400-450 degrees Celsius. The pressure and the temperature in depositing the O₃-TEOS-NSG film 8 do not substantially influence the speed of forming the film. The speed of depositing the O₃-TEOS-NSG film 8 on the first active region 100 side is faster than that of depositing the O₃-TEOS-NSG film 8 on the silicon dioxide film 5 formed on the second active region 110. Therefore, the thickness of the O₃-TEOS-NSG film 8 deposited on the first active region 100 side and that of the O₃-TEOS-NSG film 8 deposited on the second active region 110 side are different. In other words, the O₃-TEOS-NSG film 8 is thickly deposited on the first active region 100 side and is thinly deposited on the second active region 110 side.

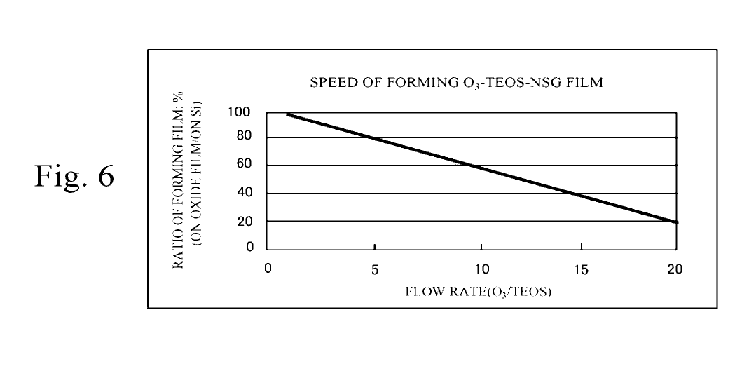

FIG. 6 is a chart showing the relationship between the flow rate of O₃ with respect to TEOS and the ratio of the speed of forming the O₃-TEOS-NSG film on the silicon dioxide with respect to the speed of forming the O₃-TEOS-NSG film on silicon in the thermal decomposition CVD method. Here, the pressure and the temperature in forming the O₃-TEOS-NSG film are set according to the above described conditions. The ratio of the speed of forming the O₃-TEOS-NSG film on silicon dioxide with respect to the speed of forming the O₃-TEOS-NSG film on silicon depends on the flow rate of O₃ with respect to TEOS. Specifically, the ratio of forming the O₃-TEOS-NSG film on silicon dioxide with respect to the speed of forming the O₃-TEOS-NSG film on silicon is approximately in inverse proportion to the flow rate of O₃ with respect to TEOS. That is to say, if the flow rate of O₃ with respect to TEOS is increased, the difference between the speed of forming the O₃-TEOS-NSG film on silicon and the speed of forming the O₃-TEOS-NSG film on silicon dioxide is increased. As a result, the difference between thickness of the O₃-TEOS-NSG film formed on silicon and that of the O₃-TEOS-NSG film formed on silicon dioxide is increased.

Specifically, when the flow rate of O₃ with respect to TEOS is set to be 10, the ratio of the speed of forming the O₃-TEOS-NSG film on silicon dioxide with respect to that of forming the O₃-TEOS-NSG film on silicon is approximately 60%. Therefore, when the flow rate of O₃ with respect to TEOS is set to be 10, the difference between thickness of the O₃-TEOS-NSG film formed on silicon dioxide and that of the O₃-TEOS-NSG film formed on silicon is approximately 40%.

When the flow rate of O₃ with respect to TEOS is set to be 15, the ratio of the speed of forming the O₃-TEOS-NSG film on silicon dioxide with respect to that of forming the O₃-TEOS-NSG film on silicon is approximately 40%. That is to say, when the flow rate of O₃ with respect to TEOS is set to be 15, the thickness of the O₃-TEOS-NSG film formed on silicon dioxide is decreased to only 40% of thickness of the O₃-TEOS-NSG film formed on silicon. Thus, the difference between thickness of the O₃-TEOS-NSG film formed on silicon dioxide and that of the O₃-TEOS-NSG film formed on silicon is increased.

Furthermore, when the flow rate of O₃ with respect to TEOS is set to be 20, the ratio of the speed of forming the O₃-TEOS-NSG film on silicon dioxide with respect to that of forming the O₃-TEOS-NSG film on silicon is approximately 20%. That is to say, when the flow rate of O₃ with respect to TEOS is set to be 20, thickness of the O₃-TEOS-NSG film formed on silicon dioxide is decreased to only 20% of thickness of the O₃-TEOS-NSG film formed on silicon. Thus, the difference between thickness of the O₃-TEOS-NSG film formed on silicon dioxide and that of the O₃-TEOS-NSG film formed on silicon is increased.

Therefore, the following can be confirmed. That is, when the substrate region comprised of silicon is compared to the substrate region comprised of silicon dioxide, the ratio of the speed of forming the O₃-TEOS-NSG film on silicon dioxide with respect to that of forming the O₃-TEOS-NSG film on silicon significantly changes according to the change in the flow rate of O₃ with respect to TEOS.

Therefore, it is understood that the flow rate of O₃ with respect to TEOS may be set to be larger if the difference between thickness of the O₃-TEOS-NSG film 8 formed on the first active region 100 side and that of the O₃-TEOS-NSG film 8 formed on the second active region 110 side must be set to be larger. On the other hand, it is understood that the flow rate of O₃ with respect to TEOS may be set to be smaller if the difference between the thickness of the O₃-TEOS-NSG film 8 formed on the first active region 100 and that of the O₃-TEOS-NSG film 8 formed on the second active region 110 must be set to be smaller. That is to say, the difference between the thickness of the O₃-TEOS-NSG film 8 formed on the first active region 100 side and that of the O₃-TEOS-NSG film 8 formed on the second active region 110 side can be regulated by regulating only the flow rate of O₃ with respect to TEOS in the thermal decomposition CVD method. In other words, the O₃-TEOS-NSG film 8 is formed on the first lightly-doped region 6-1 on the first active region 100 side and the O₃-TEOS-NSG film 8 is formed on the silicon dioxide film 5 on the second active region 110 side, and thus difference between thickness of the O₃-TEOS-NSG film 8 formed on the first active region 100 side and that of the O₃-TEOS-NSG film 8 formed on the second active region 110 side can be widely regulated by regulating only the flow rate of O₃ with respect to TEOS in the thermal decomposition CVD method, without depending on the type and the concentration of impurities doped into the first lightly-doped region 6-1 and the second lightly-doped region 6-2.

As shown in FIG. 4C, the O₃-TEOS-NSG film 8 is etched with a heretofore known anisotropic etching technique, and thus a first sidewall insulating film 9-1 is formed as the sidewall of the first gate electrode 4-1 and a second sidewall insulating film 9-2 is formed as the sidewall of the second gate electrode 4-2. Here, a heretofore known anisotropic dry etching can be used as the anisotropic etching technique. The anisotropic etching for the O₃-TEOS-NSG film 8 is conducted so that the top of the first gate electrode 4-1 corresponds to that of the first sidewall insulating film 9-1. In other words, the anisotropic etching is conducted under conditions in which the O₃-TEOS-NSG film 8 is etched on the basis of the top of the first gate electrode. The etching on the basis of the top of the first gate electrode 4-1 causes the O₃-TEOS-NSG film 8 to be over-etched with respect to the top of the second gate electrode 4-2. That is to say, the sidewall insulating film 9-1 and the second sidewall insulating film 9-2 depend on the thickness of the O₃-TEOS-NSG film 8 formed on the first active region 100 side and that of the O₃-TEOS-NSG film 8 formed on the second active region 110 side. Therefore, the thickness of the first sidewall insulating film 9-1 is formed more thickly than that of the second sidewall insulating film 9-2.

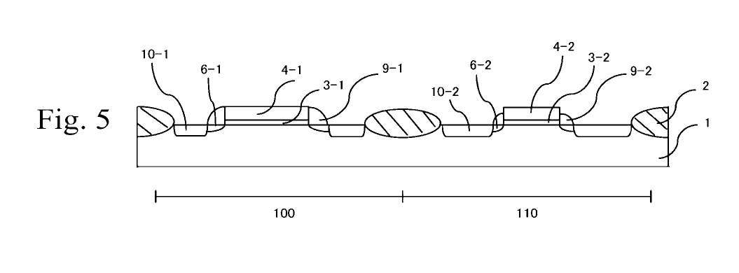

As shown in FIG. 5, the n-type impurity As is implanted into the silicon substrate 1 using the first gate electrode 4-1 and the first sidewall insulating film 9-1 as the first mask, and using the second gate electrode 4-2 and the second sidewall insulating film 9-2 as the second mask with an acceleration energy of 50 keV and a dose amount of 6.0×10¹⁵ cm⁻². Next, the thermal treatment of 950 degrees Celsius is conducted for 10 seconds and thus impurities are activated. As a result, a first heavily-doped source/drain region 10-1, which is self-aligned with respect to the sidewall insulating films 9-1, is formed in the first active region 100 of the silicon substrate 1. On the other hand, a second heavily-doped source/drain region 10-2, which is self-aligned with respect to the sidewall insulating films 9-2, is formed in the second active region 110 of the silicon substrate 1. As a result, a high voltage MOSFET is formed on the first active region 100 side and a high speed MOSFET is formed on the second active region 110 side.

Here, high gate voltage is applied to the first gate electrode 4-1 of the high voltage MOSFET, and low gate voltage is applied to the second gate electrode 4-2 of the high speed MOSFET. However, the first sidewall insulating film 9-1 is formed more thickly than the second sidewall insulating film 9-2. Therefore, the distance between the first gate electrode 4-1 and the first heavily-doped source/drain region 10-1 is longer than the distance between the second gate electrode 4-2 and the second heavily-doped source/drain region 10-2. In other words, a higher gate voltage can be applied to the high voltage MOSFET compared to the high speed MOSFET.

Here, the first heavily-doped source/drain region 10-1 and the second heavily-doped source/drain region 10-2 are simultaneously formed by conducting the ion implantation once under the same conditions. However, the method of forming these regions is not limited to the above described method. The first heavily-doped source/drain region 10-1 and the second heavily-doped source/drain region 10-2 may be separately formed in discrete ion implantation processes under different conditions.

According to the first embodiment of the present invention, a method of forming the O₃-TEOS-NSG films 8 with different thicknesses on the first active region 100 side and the second active region 110 side is provided. The O₃-TEOS-NSG film 8 is formed on the first lightly-doped region 6-1 (i.e., a silicon region) on the first active region 100 side. On the other hand, the O₃-TEOS-NSG film 8 is formed on the silicon dioxide film 5 on the second active region 110 side. Therefore, O₃-TEOS-NSG film 8 with different thicknesses are formed on the first active region 100 side and the second active region 110 side by using the difference between the speed of forming the O₃-TEOS-NSG film 8 on a silicon dioxide region and that of forming the O₃-TEOS-NSG film 8 on a silicon region. Selection of a silicon region and a silicon dioxide region as substrate regions enables the difference between thicknesses of the O₃-TEOS-NSG film 8 formed on the first active region 100 and that of the O₃-TEOS-NSG film 8 formed on the second active region 110 to be widely regulated by regulating only the flow rate of O₃ with respect to TEOS in the thermal decomposition CVD method, without depending on the type and concentration of impurities doped into the first lightly-doped region 6-1 and the second lightly-doped region 6-2. Specifically, the ratio of the speed of forming the O₃-TEOS-NSG film 8 on a silicon dioxide region with respect to that of forming the O₃-TEOS-NSG film 8 on a silicon region can be regulated to be 80-40% by regulating the flow rate of O₃ with respect to TEOS to be 5-15. In other words, the ratio of the thickness of the O₃-TEOS-NSG film 8 formed on a silicon dioxide region with respect to that of the O₃-TEOS-NSG film 8 formed on a silicon region can be regulated to be 80-40% by regulating the flow rate of O₃ with respect to TEOS to be 5-15.

Furthermore, in the ion implantation process in which the first lightly-doped region 6-1 and the second lightly-doped region 6-2 are formed, the different substrates comprised of silicon and silicon dioxide respectively are provided by reusing a thin silicon dioxide film 5 that has been already used for the purpose of protecting the surface of the silicon substrate 1. In other words, the ion implantation to form the first lightly-doped region 6-1 and the second lightly-doped region 6-2 is conducted by using the silicon dioxide film 5 as a passivation film. Then, the silicon dioxide film 5 formed on the first active region side is eliminated, while the silicon dioxide film 5 formed on the second active region 110 side is left. Thus, the substrate comprised of the first lightly-doped region 6-1 (i.e., silicon) can be formed on the first active region 100 side, and the substrate comprised of the silicon dioxide film 5 can be formed on the second active region 110 side. Therefore, a process of providing a substrate comprised of a silicon dioxide film used only for forming the O₃-TEOS-NSG film 8 is not additionally required.

Furthermore, as described above, the selection of a silicon region and a silicon dioxide region as the substrate regions enables the difference between thickness of the O₃-TEOS-NSG film 8 formed on the first active region 100 and that of the O₃-TEOS-NSG film 8 formed on the second active region 110 to be widely regulated by regulating only the flow rate of O₃ with respect to TEOS in the thermal decomposition CVD method, without depending on the type and concentration of impurities doped into the first lightly-doped region 6-1 and the second lightly-doped region 6-2. That is to say, a high degree of freedom can be assured for the type and the concentration of impurities doped into the first lightly-doped region 6-1 and the second lightly-doped region 6-2, because the type and the concentration of impurities doped into the first lightly-doped region 6-1 and the second lightly-doped region 6-2 do not influence the difference in thicknesses of the O₃-TEOS-NSG films 8.

Furthermore, the O₃-TEOS-NSG films 8 with different thicknesses are simultaneously formed in one forming process, and thus the number of manufacturing steps of a semiconductor device can be reduced. Because of this, further cost reduction can be realized. Also, in comparison with the case in which the O₃-TEOS-NSG films 8 are formed in two separate forming processes, a margin is not required to be left in consideration of the spacing error of a mask in the first embodiment of the present invention. Therefore, an unnecessary increase in chip size can be avoided.

### SECOND EMBODIMENT

Method for Manufacturing a Semiconductor Device

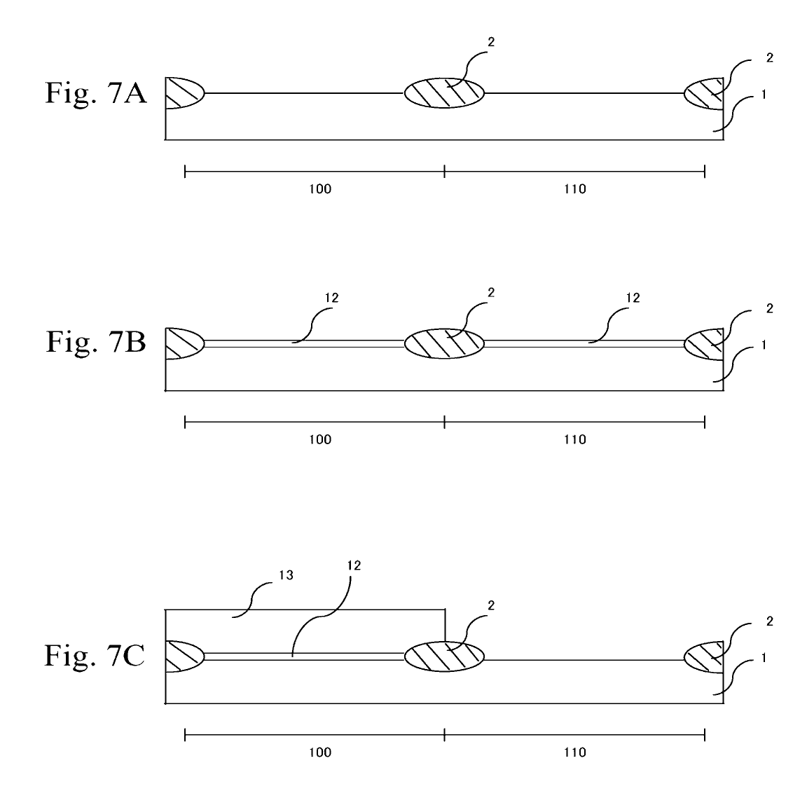

FIGS. 7A to 7C, 8A to 8C, 9A to 9C, 10A to 10C, and 11 are partial vertical cross-section diagrams showing a method for manufacturing a semiconductor device in accordance with the second embodiment of the present invention. According to the second embodiment, a high voltage MOSFET and a high speed MOSFET are formed on the same semiconductor substrate. A thick sidewall insulating film is required for the high voltage MOSFET, because the gate voltage of the high voltage MOSFET is high. On the other hand, a thin sidewall insulating film is required for the high speed MOSFET, because the gate voltage of the high speed MOSFET is low.

As shown in FIG. 7A, a field oxide film 2 is formed in element separation regions of a p-type silicon substrate 1 with the local oxidation of silicon (LOCOS) method. Thus a first active region 100 and a second active region 110 are defined by the field oxide film 2. Here, the first active region 100 is a region on which the high voltage MOSFET is formed and the second active region 110 is a region on which a high speed MOSFET is formed.

As shown in FIG. 7B, a silicon dioxide film 12 of 365 Å in thickness is formed on the first active region 100 and on the second active region 110 of the p-type silicon substrate 1.

As shown in FIG. 7C, a resist pattern 13 is formed on the silicon dioxide film 12 formed on the first active region 100 with a heretofore known lithography technique. After this, the silicon dioxide film 12 is etched using the resist pattern 13 as an etching mask. Thus, the silicon dioxide film 12 formed on the second active region 110 is selectively eliminated while the silicon dioxide film 12 formed on the first active region 100 is left.

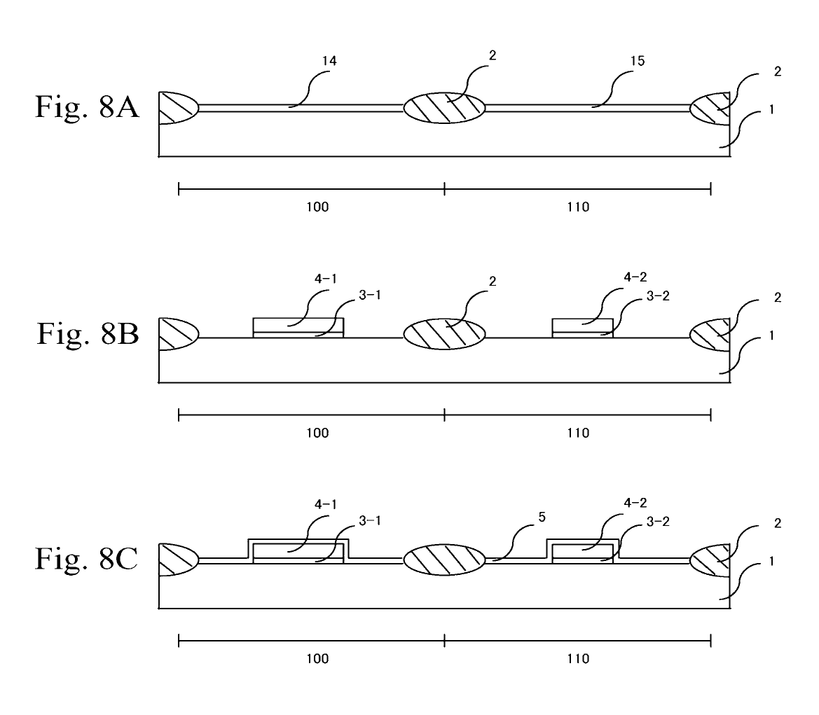

As shown in FIG. 8A, the resist pattern 13 is eliminated, and then a silicon dioxide film is formed on the silicon dioxide film 12 formed on the first active region 100 and on the second active region 110 of the p-type silicon substrate 1 with a heretofore known method. As a result, a silicon dioxide film 14 of 400 Å in thickness is formed on the first active region 100 of the silicon substrate 1, and a silicon dioxide film 15 of 75 Å in thickness is formed on the second active region 110 of the silicon substrate 1.

As shown in FIG. 8B, a polysilicon film is formed on the silicon dioxide films 14 and 15, and the field oxide film 2, and impurities are ion-implanted into this polysilicon film. Then, the polysilicon film including the impurities and the silicon dioxide films 14 and 15 are patterned with a heretofore known lithography technique and etching technique. Thus, a first gate oxide film 3-1 and a first gate electrode 4-1 are formed on the first active region 100, and a second gate oxide film 3-2 and a second gate electrode 4-2 are formed on the second active region 110.

As shown in FIG. 8C, a silicon dioxide film 5 of 100 Å-500 Å in thickness is formed with the thermal oxidation method or the CVD method, so that it covers the upper surface of the first active region 100, the lateral surface of the first gate oxide film 3-1, and the upper and the lateral surfaces of the first gate electrode 4-1, as well as the upper surface of the second active region 110, the lateral surface of the second gate oxide film 3-2, and the upper and the lateral surfaces of the second gate electrode 4-2.

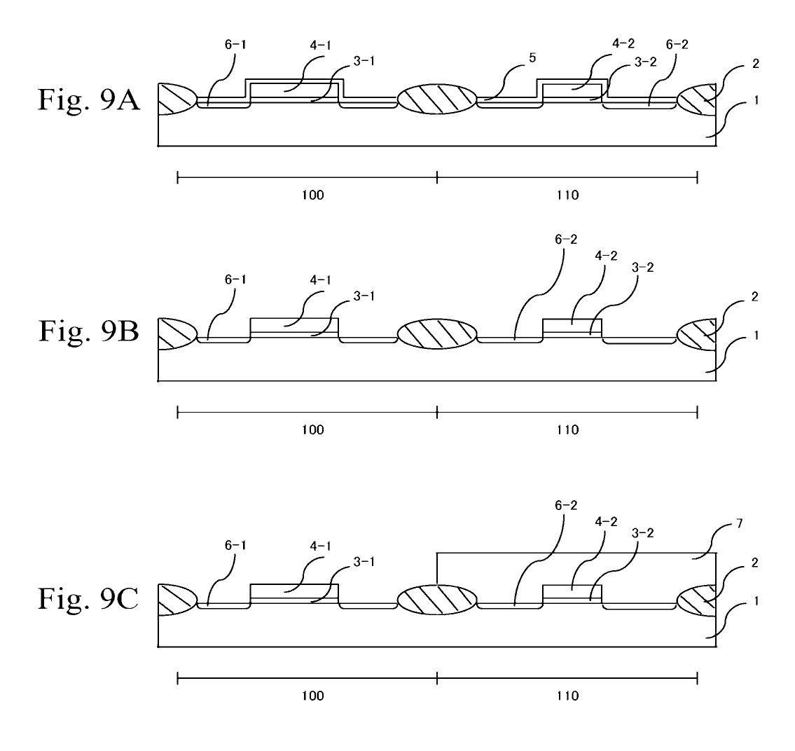

As shown in FIG. 9A, the n-type impurity arsenic (As) is implanted into the silicon substrate 1 using the first gate electrode 4-1, the second gate electrode 4-2, and the field oxide film 2 as masks with an acceleration energy of 20 keV and the dose amount of 1.2×10¹⁴ cm⁻². As a result, a first lightly-doped region 6-1, which is self-aligned with respect to the first gate electrode 4- 1, is formed in the first active region 100 of the silicon substrate 1. On the other hand, a second lightly-doped region 6-2, which is self-aligned with respect to the second gate electrode 4-2, is formed in the second active region 110 of the silicon substrate 1.

Here, the thickness of the sufficiently thin silicon dioxide film 5 enables the accelerated ions to pass through the silicon dioxide film 5 and to be implanted into the silicon substrate 1. Also, the silicon dioxide film 5 formed on the surface of the silicon substrate 1 prevents the surface of the silicon substrate 1 from being damaged by the ion implantation. Furthermore, the silicon dioxide film 5 prevents the surface of the silicon substrate 1 from being contaminated by metal.

Here, the first lightly-doped region 6-1 and the second lightly-doped region 6-2 are simultaneously formed by conducting the ion implantation once under the same condition. However, the method of forming these regions is not limited to the above described method. For example, the first lightly-doped region 6-1 and the second lightly-doped region 6-2 may be separately formed in discrete ion implantation processes under different conditions.

As shown in FIG. 9B, the silicon dioxide film 5 is eliminated with a heretofore known method.

As shown in FIG. 9C, a resist pattern 7 is formed so that it covers the upper surface of the second lightly-doped region 6-2, on the upper and lateral surfaces of the second gate electrode 4-2, the lateral surface of the second gate oxide film 3-2, and surface of the field oxide film, which are all formed on the second active region 110 side.

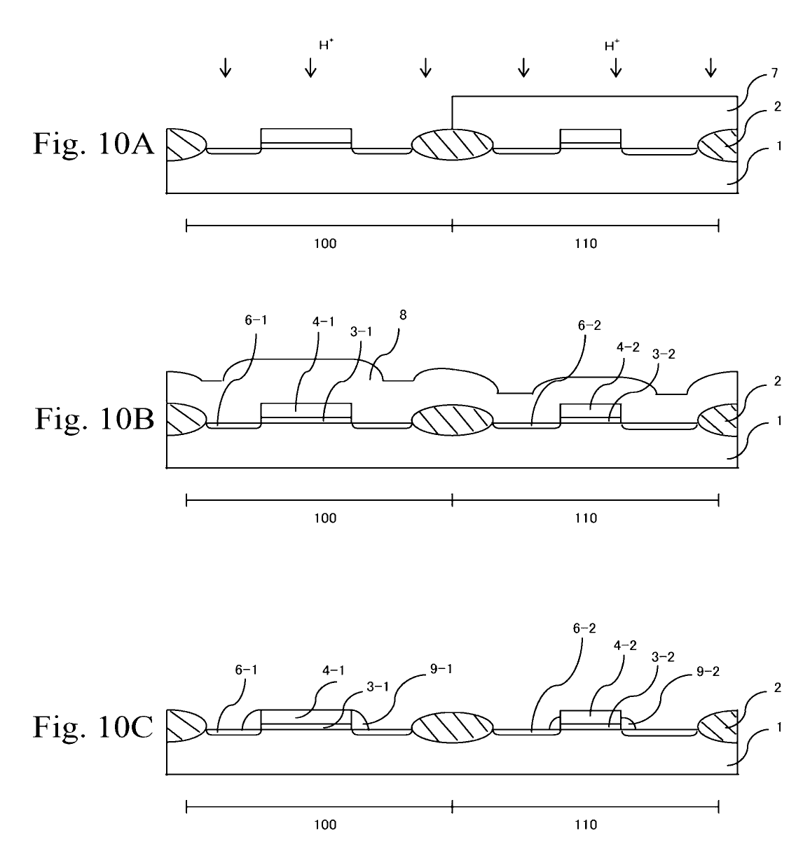

As shown in FIG. 10A, hydrogen ion (H⁺) is selectively ion-implanted into the first active region 110 using the resist pattern 7 as a mask. The ion implantation can be conducted with an acceleration energy of 10 keV and a dose amount of 1×10¹³-1×10¹⁵ cm⁻².

As shown in FIG. 10B, non-doped silicate glass (NSG) film 8 (hereinafter called a O₃-TEOS-NSG film) is deposited on the first active region 100 side into which H⁺ is implanted and on the second active region 110 side into which H⁺ is not implanted by the thermal decomposition CVD method in which ozone (O₃) and tetraethoxysilane (TEOS) are used as materials.

In forming the O₃-TEOS-NSG film 8, the thermal decomposition CVD method can be conducted under the desired conditions. However, as a typical example, the following conditions are set. That is, the flow rate of O₃ with respect to TEOS is set to be 10-20, and the pressure is set to be a normal pressure, and the temperature is set to be 400 degrees Celsius. The ratio of the thickness of the O₃-TEOS-NSG film 8 formed on the second active region 110 side is 80-60% of that of the O₃-TEOS-NSG film 8 formed on the first active region 100. In depositing the O₃-TEOS-NSG film 8, the pressure may be typically set to be 400-760 Torr and the temperature may be typically set to be 400-450 degrees Celsius. The pressure and the temperature in depositing the O₃-TEOS-NSG film 8 do not substantially influence the speed of forming the film. The speed of depositing the O₃-TEOS-NSG film 8 on the exposed surface of silicon into which H⁺ is implanted is faster than that of depositing the O₃-TEOS-NSG film 8 on the exposed surface of silicon into which H⁻ is not implanted. Therefore, the thickness of the O₃-TEOS-NSG film 8 deposited on the first active region 100 side and that of the O₃-TEOS-NSG film 8 deposited on the second active region 110 side are different. In other words, the O₃-TEOS-NSG film 8 is thickly deposited on the first active region 100 side and it is thinly deposited on the second active region 110 side.

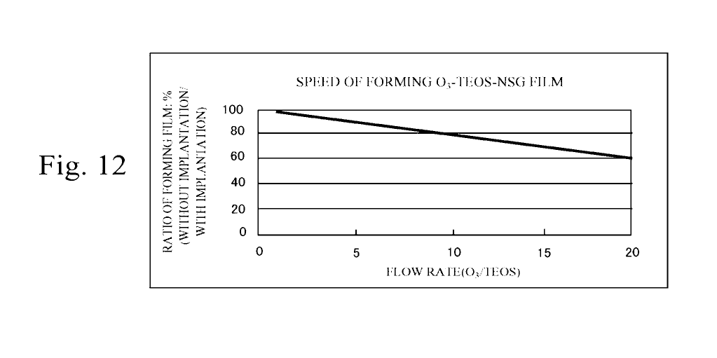

FIG. 12 is a chart showing the relationship between the flow rate of O₃ with respect to TEOS and the ratio of the speed of forming the O₃-TEOS-NSG film on silicon into which H⁺ is not implanted with respect to the speed of forming the O₃-TEOS-NSG film on silicon into which H⁺ is implanted in the thermal decomposition CVD method. Here, the pressure and the temperature in forming the O₃-TEOS-NSG film are set according to the above described conditions. The ratio of the speed of forming the O₃-TEOS-NSG film on silicon into which H⁺ is not implanted with respect to that of forming the O₃-TEOS-NSG film on silicon into which H⁺ is implanted depends on the flow rate of O₃ with respect to TEOS. Specifically, the ratio of forming the O₃-TEOS-NSG film on silicon into which H⁺ is not implanted with respect to that of forming the O₃-TEOS-NSG film on silicon into which H⁺ is implanted is approximately in inverse proportion to the flow rate of O₃ with respect to TEOS. That is to say, if the flow rate of O₃ with respect to TEOS is increased, the difference between the speed of forming the O₃-TEOS-NSG film on silicon into which H⁺ is implanted and that of forming the O₃-TEOS-NSG film on silicon into which H⁺ is not implanted is increased. As a result, the difference between thickness of the O₃-TEOS-NSG film formed on silicon into which H⁺ is implanted and that of forming the O₃-TEOS-NSG film on silicon into which H⁺ is not implanted is increased.

Specifically, when the flow rate of O₃ with respect to TEOS is set to be 10, the ratio of the speed of forming the O₃-TEOS-NSG film on silicon dioxide with respect to that of forming the O₃-TEOS-NSG film on silicon into which H⁺ is implanted is approximately 80%. That is to say, when the flow rate of O₃ with respect to TEOS is set to be 10, the difference between the thickness of the O₃-TEOS-NSG film formed on silicon and that of the O₃-TEOS-NSG film formed on silicon into which H⁺ is not implanted is approximately 20%.

When the flow rate of O₃ with respect to TEOS is set to be 20, the ratio of the speed of forming the O₃-TEOS-NSG film on silicon into which H⁺ is not implanted with respect to that of forming the O₃-TEOS-NSG film on silicon into which H⁺ is implanted is approximately 60%. That is to say, when the flow rate of O₃ with respect to TEOS is set to be 20, the thickness of the O₃-TEOS-NSG film formed on silicon into which H⁺ is not implanted is decreased to only 60% of thickness of the O₃-TEOS-NSG film formed on silicon into which H⁺ is implanted. Thus, the difference between the thickness of the O₃-TEOS-NSG film formed on silicon into which H⁺ is not implanted and that of the O₃-TEOS-NSG film formed on silicon into which H⁺ is implanted is greatly increased.

When the substrate region comprised of silicon into which H⁺ is implanted and the substrate region comprised of silicon into which H⁺ is not implanted are used, the following can be confirmed. That is, the ratio of the speed of forming the O₃-TEOS-NSG film on silicon into which H⁺ is not implanted with respect to that of forming the O₃-TEOS-NSG film on silicon into which H⁺ is implanted significantly changes according to the change of the flow rate of O₃ with respect to TEOS.

Therefore, it is understood that the flow rate of O₃ with respect to TEOS may be set to be larger if the difference between thickness of the O₃-TEOS-NSG film 8 formed on the first active region 100 side and that of the O₃-TEOS-NSG film 8 formed on the second active region 110 side must be set to be larger. On the other hand, it is understood that the flow rate of O₃ with respect to TEOS may be set to be smaller if the difference between the thickness of the O₃-TEOS-NSG film 8 formed on the first active region 100 and that of the O₃-TEOS-NSG film 8 formed on the second active region 110 must be set to be smaller. That is to say, the difference between the thickness of the O₃-TEOS-NSG film 8 formed on the first active region 100 side and that of the O₃-TEOS-NSG film 8 formed on the second active region 110 side can be regulated by regulating only the flow rate of O₃ with respect to TEOS in the thermal decomposition CVD method. In other words, the O₃-TEOS-NSG films 8 is formed on the first lightly-doped region 6-1 into which H⁺ is implanted on the first active region 100 side and the O₃-TEOS-NSG film 8 is formed on the second lightly-doped region 6-2 into which H⁺ is not implanted on the second active region 110 side, and thus the difference between the thickness of the O₃-TEOS-NSG films 8 formed on the first active region 100 and that of the O₃-TEOS-NSG films 8 formed on the second active region 110 can be widely regulated by regulating only the flow rate of O₃ with respect to TEOS in the thermal decomposition CVD method, without depending on the type and the concentration of impurities doped into the first lightly-doped region 6-1 and the second lightly-doped region 6-2.

As shown in FIG. 10C, the O₃-TEOS-NSG film 8 is etched with a heretofore known anisotropic etching technique, and thus a first sidewall insulating film 9-1 is formed as the sidewall of the first gate electrode 4-1 and a second sidewall insulating film 9-2 is formed as the sidewall of the second gate electrode 4-2. Here, a heretofore known anisotropic dry etching can be used as the anisotropic etching technique. The anisotropic etching for the O₃-TEOS-NSG film 8 is conducted so that the top of the first gate electrode 4-1 corresponds to that of the first sidewall insulating film 9-1. In other words, the anisotropic etching is conducted under conditions in which the O₃-TEOS-NSG film 8 is etched on the basis of the top of the first gate electrode 4-1. The etching on the basis of the top of the first gate electrode 4-1 causes the O₃-TEOS-NSG film 8 to be over-etched with respect to the top of the second gate electrode 4-2. That is to say, the sidewall insulating film 9-1 and the second sidewall insulating film 9-2 depend on the thickness of the O₃-TEOS-NSG film 8 formed on the first active region 100 side and that of the O₃-TEOS-NSG film 8 formed on the second active region 110 side. Therefore, the thickness of the first sidewall insulating film 9-1 is formed more thickly than that of the second sidewall insulating film 9-2.

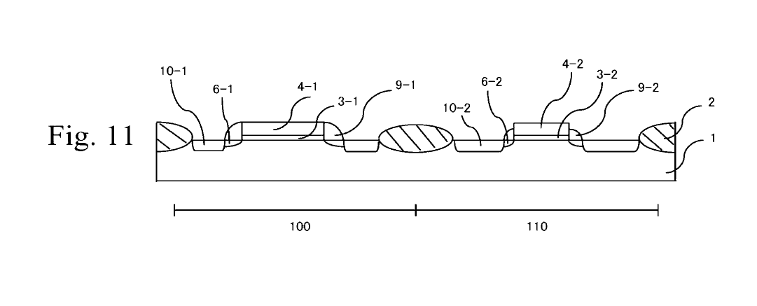

As shown in FIG. 11, the n-type impurity As is implanted into the silicon substrate 1 using the first gate electrode 4-1 and the first sidewall insulating film 9-1 as the first mask, and using the second gate electrode 4-2 and the second sidewall insulating film 9-2 as the second mask under with an acceleration energy of 50 keV and a dose amount of 6.0×10¹⁵ cm⁻². Next, a thermal treatment of 950 degrees Celsius is conducted for 10 seconds and thus impurities are activated. As a result, a first heavily-doped source/drain region 10-1, which is self-aligned with respect to the sidewall insulating films 9-1, is formed in the first active region 100 of the silicon substrate 1. On the other hand, a second heavily-doped source/drain region 10-2, which is self-aligned with respect to the sidewall insulating films 9-2, is formed in the second active region 110 of the silicon substrate 1. As a result, a high voltage MOSFET is formed on the first active region 100 side and a high speed MOSFET is formed on the second active region 110 side.

Here, high gate voltage is applied to the first gate electrode 4-1 of the high voltage MOSFET, and low gate voltage is applied to the second gate electrode 4-2 of the high speed MOSFET. However, the first sidewall insulating film 9-1 is formed more thickly than the second sidewall insulating film 9-2. Therefore, the distance between the first gate electrode 4-1 and the first heavily-doped source/drain region 10-1 is longer than distance between the second gate electrode 4-2 and the second heavily-doped source/drain region 10-2. In other words, a higher gate voltage can be applied to the high voltage MOSFET compared to the high speed MOSFET.

Here, the first heavily-doped source/drain region 10-1 and the second heavily-doped source/drain region 10-2 are simultaneously formed by conducting the ion implantation once under the same conditions. However, the method of forming these regions is not limited to the above described method. The first heavily-doped source/drain region 10-1 and the second heavily-doped source/drain region 10-2 may be separately formed in discrete ion implantation processes under different conditions.

According to the second embodiment of the present invention, a method of forming the O₃-TEOS-NSG films 8 with different thicknesses on the first active region 100 side and the second active region 110 side is provided. The O₃-TEOS-NSG film 8 is formed on the first lightly-doped region 6-1 into which H⁺ is implanted on the first active region 100 side. On the other hand, O₃-TEOS-NSG film 8 is formed on the second lightly-doped region 6-2 into which H⁺ is not implanted on the second active region 110 side. Therefore, the O₃-TEOS-NSG film 8 with different thicknesses are formed on the first active region 100 side and the second active region 110 side by using the difference between the speed of forming the O₃-TEOS-NSG film 8 on a silicon region into which H⁺ is implanted and that of forming the O₃-TEOS-NSG film 8 on a silicon region into which H⁺ is not implanted. The selective implantation of H⁺ enables the difference between thickness of the O₃-TEOS-NSG film 8 formed on the first active region 100 side and that of the O₃-TEOS-NSG film 8 formed on the second active region 110 side to be widely regulated by regulating only the flow rate of O₃ with respect to TEOS in the thermal decomposition CVD method, without depending on the type and concentration of impurities doped into the first lightly-doped region 6-1 and the second lightly-doped region 6-2. Specifically, the ratio of the speed of forming the O₃-TEOS-NSG film 8 on a silicon region into which H+ is not implanted with respect to that of forming the O₃-TEOS-NSG film 8 on a silicon region into which H+ is implanted can be regulated to be 80-60% by regulating the flow rate of O₃ with respect to TEOS to be 10-20. In other words, the ratio of the thickness of the O₃-TEOS-NSG film 8 formed on a silicon region into which H+ is not implanted with respect to that of the O₃-TEOS-NSG film 8 formed on a silicon region into which H+ is implanted can be regulated to be 80-60 by regulating the flow rate of O₃ with respect to TEOS to be 10-20.

Furthermore, it is important to select the positive ion H⁺ whose ion type is different from the impurities doped into the first lightly-doped region 6-1 and whose atomic mass is the smallest. The speed of forming the O₃-TEOS-NSG film 8 formed on silicon is accelerated by implanting positive ions into the silicon. Here, the selection of H+ that has significantly smaller atomic mass compared to the impurity As doped into the first lightly-doped region 6-1 and the second lightly-doped region 6-2 enables the first lightly-doped region 6-1 to be protected from damage and also enables the speed of forming the O₃-TEOS-NSG film 8 to be increased.

Furthermore, as described above, selection of a silicon region into which H+ is implanted and a silicon region into which H+ is not implanted as the substrate regions enables difference of thicknesses of the O₃-TEOS-NSG film 8 formed on the first active region 100 side and the second active region 110 side to be widely regulated by regulating only the flow rate of O₃ with respect to TEOS in the thermal decomposition CVD method, without depending on the type and concentration of impurities doped into the first lightly-doped region 6-1 and the second lightly-doped region 6-2. That is to say, a high degree of freedom can be assured for the type and the concentration of impurities doped into the first lightly-doped region 6-1 and the second lightly-doped region 6-2, because the type and the concentration of impurities doped into the first lightly-doped region 6-1 and the second lightly-doped region 6-2 do not substantially influence the difference in thicknesses of the O₃-TEOS-NSG films 8.

Furthermore, the O₃-TEOS-NSG films 8 with different thicknesses are simultaneously formed in one forming process, and thus the number of manufacturing steps of a semiconductor device can be reduced. Because of this, further cost reduction can be realized. Also, compared to the case in which the O₃-TEOS-NSG films 8 are formed in two separate forming processes, a margin is not required to be left in consideration of the spacing error of a mask in the second embodiment of the present invention. Therefore, an unnecessary increase in chip size can be avoided.

The above described H+ ion implantation process of may be conducted before the O₃-TEOS-NSG film 8 is formed, and it also may be conducted before or after the first lightly-doped region 6-1 and the second lightly-doped region 6-2 are formed.

As described above, in the first and the second embodiments of the present invention, a n-channel high voltage MOSFET and a n-channel high speed MOSFET are formed on a p-type silicon substrate. However, the present invention can be applied to a situation in which a p-channel high voltage MOSFET and a p-channel high speed MOSFET are formed on a n-type silicon substrate. Also, the present invention can be applied to a situation in which a well region is formed on a silicon substrate and a high voltage MOSFET and a high speed MOSFET whose conductivity types are different with each other are formed on this well region.

This application claims priority to Japanese Patent Application No. 2005-067620. The entire disclosure of Japanese Patent Application No. 2005-067620 is hereby incorporated herein by reference.

The terms of degree, such as “sufficiently” and “substantially,” used herein mean a reasonable amount of deviation of the modified term such that the end result is not significantly changed. For example, the terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

What is claimed is:

1. A method for manufacturing a semiconductor device having sidewall insulating films with different thicknesses, comprising the steps of:
selectively forming a first gate electrode structure and a second gate electrode structure on a first active region and a second active region of a silicon substrate, respectively;
forming a first silicon oxide film on said first active region and said second active region;
forming a first lightly-doped region and a second lightly-doped region in said first active region and said second active region, respectively, by ion-implanting impurities into said first active region and said second active region through said first silicon oxide film;
removing said first silicon oxide film formed on said first active region while leaving said first silicon oxide film formed on said second active region;
forming an insulating film on said first region of said silicon substrate and an insulating film on said first silicon oxide film formed on said second active region of said silicon substrate with a thermal decomposition CVD method in which ozone and tetraethoxysilane are used as materials, said insulating film formed on said first region of said silicon substrate being formed more thickly than said insulating film formed on said first silicon oxide film formed on said second active region of said silicon substrate; and
forming a first sidewall insulating film on a sidewall of said first gate electrode structure while forming a second sidewall insulating film on a sidewall of said second gate electrode structure, said first sidewall insulating film being formed more thickly than said second sidewall insulating film.

2. The method according to claim 1, wherein said thermal decomposition CVD method is conducted under conditions in which the flow rate of ozone with respect to tetraethoxysilane is set to be 5-15.

3. The method according to claim 1, wherein said first silicon oxide film has a thickness of 100-500 Å.

4. The method according to claim 1, wherein said first lightly-doped region and said second lightly-doped region include impurities whose conductivity types are the same.

5. A method for manufacturing a semiconductor device having sidewall insulating films with different thicknesses, comprising the steps of:
selectively forming a first gate electrode structure and a second gate electrode structure on a first active region and a second active region of a silicon substrate, respectively;
forming a first lightly-doped region and a second lightly-doped region in said first active region and a second active region;
ion-implanting hydrogen into only said first active region;
forming an insulating film on said first active region of said silicon substrate in which hydrogen ion is implanted and said second active region of said first silicon substrate in which hydrogen ion is not implanted with a thermal decomposition CVD method in which ozone and tetraethoxysilane are used as materials, said insulating film formed on said first active region of said silicon substrate being formed more thickly than said insulating film formed on said second active region of said silicon substrate; and
forming a first sidewall insulating film and a second sidewall insulating film on a sidewall of said first gate electrode structure and a sidewall of said second gate electrode structure, respectively, by etching said insulating film, said second sidewall insulating film being formed more thinly than said first sidewall insulating film.

6. The method according to claim 5, wherein said thermal decomposition CVD method is conducted under conditions in which the flow rate of ozone with respect to tetraethoxysilane is set to be 10-20.

7. The method according to claim 5, wherein said first lightly-doped region and said second lightly-doped region include impurities whose conductivity types are the same.

8. A method for regulating the speed at which an insulating film is formed in a thermal decomposition CVD method in which ozone and tetraethoxysilane are used as materials, the method comprising the step of:
regulating the flow rate of the ozone with respect to the tetraethoxysilane in order to regulate the ratio of the speed of forming said insulating film on a second region comprised of silicon oxide with respect to the speed of forming said insulating film on a first region comprised of silicon.

9. The method according to claim 8, wherein said flow rate of ozone with respect to tetraethoxysilane is regulated to be 5-15.

10. A method for regulating the speed of forming an insulating film in a thermal decomposition CVD method in which ozone and tetraethoxysilane are used as materials, the method comprising the step of:
regulating the flow rate of ozone with respect to tetraethoxysilane in order to regulate the ratio of the speed of forming said insulating film on a second active region that is comprised of silicon in which hydrogen ion is not implanted with respect to the speed of forming said insulating film on a first active region that is comprised of silicon in which hydrogen ion is implanted.

11. The method according to claim 10, wherein said flow rate of ozone with respect to tetraethoxysilane is regulated to be 10-20.
